(19) United States
(12) Patent Application Publication
(10) Pub. No.: US 2008/0283891 A1
(43) Pub. Date: Nov. 20, 2008

(54) SEMICONDUCTOR STRUCTURE AND MANUFACTURING METHOD THEREOF

(75) Inventors: Jack Lee, Hsinchu County (TW); Herbert Lu, Hsinchu City (TW); Marvin Liu, Hsinchu City (TW); Peter Pong, Hsinchu County (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 11/756,429

(22) Filed: May 31, 2007

(30) Foreign Application Priority Data
May 16, 2007 (TW) 096117336

(51) Int. Cl. H01L 21/8242; H01L 29/68

(52) U.S. Cl. 257/301; 438/107; 257/E29.17; 257/E21.646

(57) ABSTRACT

A semiconductor structure comprises a first wafer and a second wafer, between which a glue layer can be used for combination. The first wafer comprises a first semiconductor cell structure, and a surface of the first wafer comprises conductive pads electrically connected to the first semiconductor cell structure. The second wafer comprises a second semiconductor cell structure and is bonded to the surface of the first wafer having the conductive pads. The first and second semiconductor cell structures are electrically connected through the conductive pads, and the conductive pads are formed around each die of the first wafer. The density of the first semiconductor cell structure in the first wafer is larger than the density of the second semiconductor cell structure in the second wafer.

### BACKGROUND OF THE INVENTION

(A) Field of the Invention

The present invention relates to a semiconductor structure and manufacturing method thereof, and more specifically, to a semiconductor structure and manufacturing method thereof using wafer-bonding technology.

(B) Description of the Related Art

The so-called embedded dynamic random access memory (embedded DRAM) integrates logic circuitry and DRAM circuitry on a chip. Because the chip contains both logic and DRAM circuits, the number of chips on a circuit board using such design can be reduced. In addition, propagation delay between different circuits can be eliminated, and power consumption of the chip can be reduced as well.

With traditional embedded DRAM, a DRAM structure is fabricated first and at that time a logic area is protected by a mask. Therefore, the substrate of the logic area would not be damaged while fabricating the DRAM structure. Likewise, the fabricated DRAM structure is masked also during the processes of fabricating the logic circuit.

FIG. 1 illustrates a traditional embedded DRAM structure 10, in which deep trenches 12 serving as memory capacitors are formed in a semiconductor substrate 11, and n-wells or p-wells are formed by ion implantation or doping technology. Transistors 14, interconnection lines 15 and metal lines 16 are formed sequentially. A DRAM structure including deep trenches 12 serving as memory capacitors is fabricated on the left side of the embedded DRAM structure 10, and logic circuitry is fabricated on the right side.

With continuing improvements in semiconductor technology, line width gradually shrinks to increase integration density However, as devices become closer, manufacture becomes more difficult and integration density is limited. Moreover, some problems such as crosslink, timing delay and thermal effect may occur.

In view of the limitation of integration intensity for embedded DRAM with continuing developments, if embedded DRAM can break through the limitation, the applications for embedded DRAM could be expanded.

### SUMMARY OF THE INVENTION

The present invention provides a semiconductor structure and manufacturing method thereof, with a view to increasing device density, and providing various semiconductor structures to increase the diversity of device design.

In accordance with the present invention, a semiconductor structure comprises a first wafer and a second wafer, between which a glue layer can be used for combination. The first wafer comprises a first semiconductor cell structure, and a surface of the first wafer comprises conductive pads electrically connected to the first semiconductor cell structure. The second wafer comprises a second semiconductor cell structure and is bonded to the surface of the first wafer having the conductive pads. The first and second semiconductor cell structures are electrically connected through the conductive pads, and the conductive pads are formed around the perimeter of each die of the first wafer. The density of the first semiconductor cell structure in the first wafer is larger than the density of the second semiconductor cell structure in the second wafer.

Given that the first semiconductor cell structure is DRAM and the second semiconductor cell structure is a logic circuit structure, the first wafer including the first semiconductor cell structure is ready for sale, and the logic circuit can be formed on a second wafer bonded to the first wafer by another manufacturer, so as to form embedded DRAM including DRAM and logic circuits. For instance, standardized DRAM can be fabricated by a professional DRAM manufacturer, and various logic circuits are fabricated by foundries, so that each of the manufacturers can focus on its specialty.

In manufacturing, a deep trench DRAM is formed first on the first wafer, in which electrical connection lines and pad layers are sequentially formed on metal lines of the DRAM so as to form conductive pads. The first and second wafers are bonded afterwards, and the second semiconductor cell structure of the second wafer is electrically connected to the first semiconductor cell structure of the first wafer through the conductive pads.

### BRIEF DESCRIPTION OF THE DRAWINGS

FIG. 1 illustrates a known embedded DRAM structure;

FIG. 2 illustrates the manufacturing process of the semiconductor structure in accordance with the present invention;

FIG. 3 illustrates a die of the first wafer of the semiconductor structure in accordance with the present invention; and

FIG. 4 illustrates a cross-sectional profile of a conductive pad shown in FIG. 3.

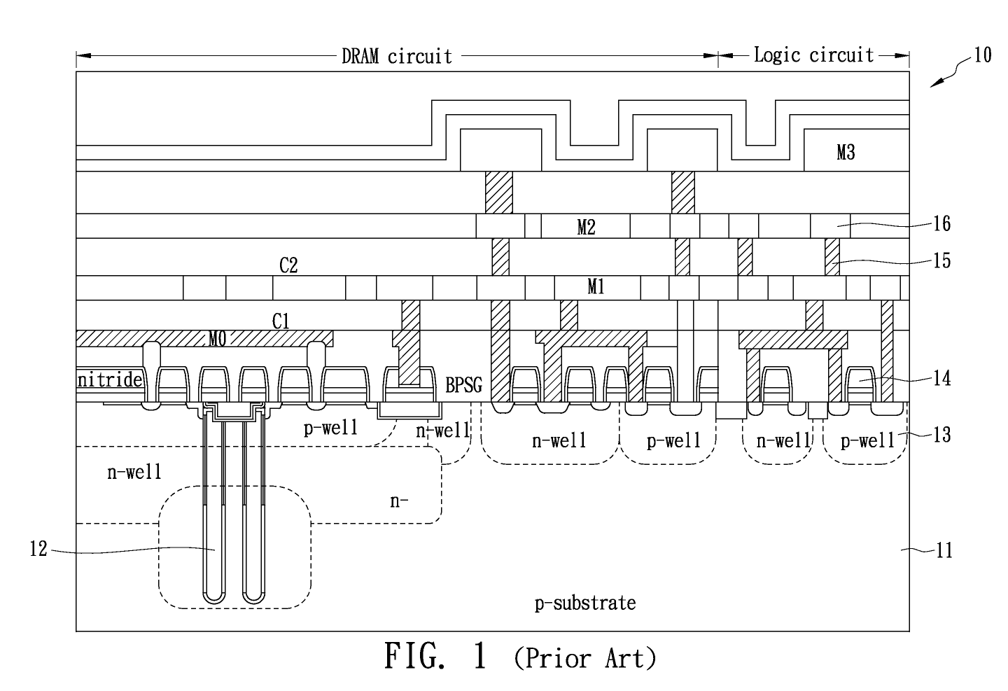

### DETAILED DESCRIPTION OF THE INVENTION

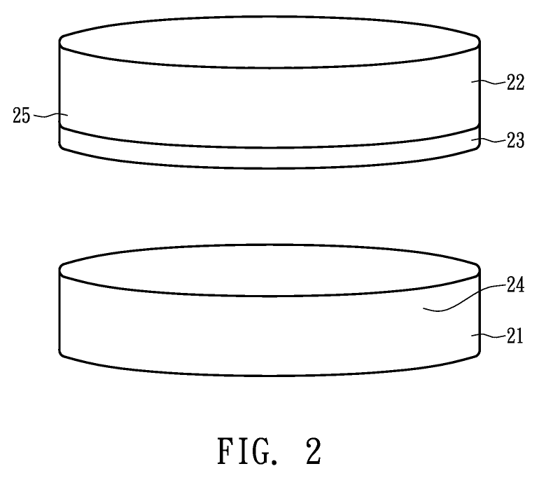

FIG. 2 illustrates the manufacturing of a semiconductor structure in accordance with the present invention, in which two wafers 21 and 22 are combined by wafer bonding technology, and a glue layer 23 is between the wafers 21 and 22. The wafer 21 includes a semiconductor cell structure 24, and the wafer 22 includes another semiconductor cell structure. The two wafers 21 and 22 include either similar semiconductor cell structures, e.g., DRAMs, or different semiconductor cell structures, e.g., a logic device structure and a DRAM structure; or a memory circuit and a solar cell circuit, thereby providing diversity of combinations. In this embodiment, the glue layer 23 includes titanium.

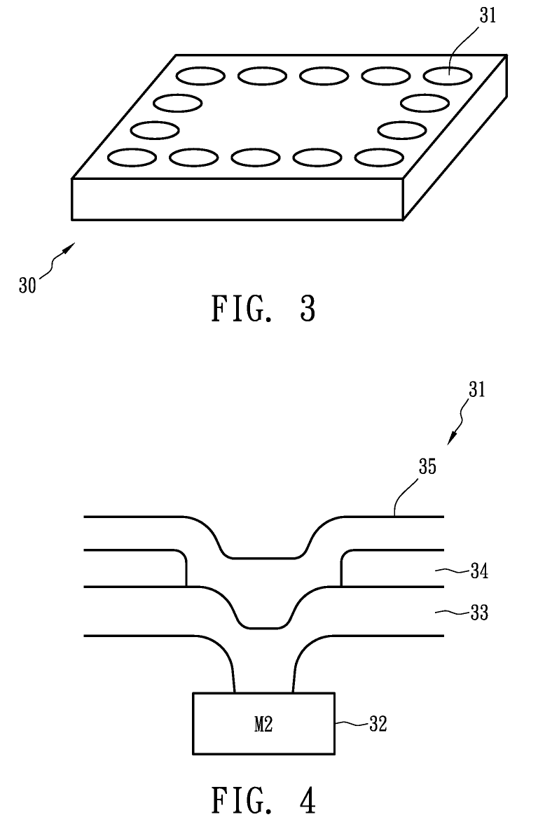

Referring to FIG. 3, during manufacturing of the wafer 21, conductive pads 31 are formed around the perimeter of a die 30 of the wafer 21 for electrical conduction of the semiconductor cell structure 24 of the lower wafer 21 and the semiconductor cell structure 25 of the upper wafer 22.

FIG. 4 illustrates a cross-sectional profile of the conductive pad 31, in which an electrical connection line 33 is formed on a metal line (M2) 32 of the DRAM structure, and a dielectric layer 34 is deposited thereon for insulation. An opening of the dielectric layer 34 is formed above the electrical connection line 33, and a pad layer 35 is formed on the electrical connection line 33 in the opening.

As a result, if the semiconductor cell structure 25 of the wafer 22 includes logic circuitry, the logic circuit can be electrically connected to the DRAM circuit of the wafer 21 after the upper wafer 22 is bonded with the lower wafer 21.

Generally, the integration density of the DRAM structure is larger than that of the logic structure. In accordance with the above embodiment, the density the DRAM structure of the lower wafer is larger than that of the logic structure of the upper wafer. In view of the DRAM structure of high density, it is suitable for electrical connection to the logic circuit having lower density as well as the arrangement of the logic circuit.

In practice, a first wafer including a first semiconductor cell structure is ready for sale, and the logic circuit can be added in a second wafer by another manufacturer, so as to form the embedded DRAM including DRAM and logic circuits. Accordingly, manufacturing flexibility can be further improved.

The above-described embodiments of the present invention are intended to be illustrative only. Numerous alternative embodiments may be devised by those skilled in the art without departing from the scope of the following claims.

What is claimed is:

1. A semiconductor structure, comprising:
a first wafer comprising a first semiconductor cell structure, and a surface of the first wafer comprising conductive pads electrically connected to the first semiconductor cell structure; and
a second wafer comprising a second semiconductor cell structure and being bonded to the surface of the first wafer having the conductive pads;
wherein the first and second semiconductor cell structures are electrically connected through the conductive pads, and the density of the first semiconductor cell structure in the first wafer is larger than the density of the second semiconductor cell structure in the second wafer.

2. The semiconductor structure in accordance with claim 1, wherein the first semiconductor cell structure is a DRAM structure and the second semiconductor cell structure is a logic circuit structure.

3. The semiconductor structure in accordance with claim 2, wherein the DRAM structure has deep trench capacitors.

4. The semiconductor structure in accordance with claim 1, wherein the first wafer and the second wafer are bonded by a glue layer.

5. The semiconductor structure in accordance with claim 4, wherein the glue layer comprises titanium.

6. The semiconductor structure in accordance with claim 1, wherein the conductive pads are formed around the perimeter of a die of the first wafer.

7. The semiconductor structure in accordance with claim 2, wherein the conductive pads are connected to metal lines of the DRAM structure and the conductive pads comprise an electrical connection line and a pad layer.

8. The semiconductor structure in accordance with claim 7, wherein the electrical connection line is formed on the metal line, and the pad layer is connected to a surface of the electrical connection line and the second semiconductor cell structure of the second wafer.

9. A semiconductor structure, comprising:
a first wafer comprising a first semiconductor cell structure, and a surface of the first wafer comprising conductive pads electrically connected to the first semiconductor cell structure;
wherein the conductive pads are configured to electrically connect the first semiconductor cell structure and a second semiconductor cell structure of a second wafer after the first wafer is bonded to the second wafer.

10. The semiconductor structure in accordance with claim 9, wherein the conductive pads are formed around the perimeter of a die of the first wafer.

11. The semiconductor structure in accordance with claim 9, wherein the first semiconductor cell structure is a DRAM structure.

12. The semiconductor structure in accordance with claim 11, wherein the conductive pads are connected to metal lines of the DRAM structure and the conductive pads comprise an electrical connection line and a pad layer.

13. The semiconductor structure in accordance with claim 12, wherein the electrical connection line is formed on the metal lines and the pad layer is formed on the electrical connection line.

14. A method for manufacturing a semiconductor structure, comprising:
providing a first wafer including a first semiconductor cell structure and a surface of the first wafer comprising conductive pads electrically connected to the first semiconductor cell structure;
providing a second wafer including a second semiconductor cell structure; and
bonding the first and second wafers in which the second semiconductor cell structure is electrically connected to the first semiconductor cell structure through the conductive pads;
wherein the density of the first semiconductor cell structure in the first wafer is larger than the density of the second semiconductor cell structure in the second wafer.

15. The method in accordance with claim 14, wherein the conductive pads are formed around the perimeter of a die of the first wafer.

16. The method in accordance with claim 14, wherein the first wafer and the second wafer are bonded by a glue layer.

17. The method in accordance with claim 14, wherein the first semiconductor cell structure is a DRAM structure, and the second semiconductor cell structure is a logic circuit structure.

18. The method in accordance with claim 17, wherein the DRAM structure comprises deep trench capacitors.

19. The method in accordance with claim 17, wherein the conductive pads are fabricated by sequentially forming an electrical connection line and a pad layer on a metal line of the DRAM structure, wherein the pad layer is electrically connected to the metal line.
